(19) United States
(12) Patent Application Publication
(10) Pub. No.: US 2015/0346408 A1
(43) Pub. Date: Dec. 3, 2015

(54) OPTICAL FILM WITH PRESSURE SENSITIVE ADHESIVE ON BOTH SIDES AND METHOD FOR PRODUCING IMAGE DISPLAY DEVICE USING SAME

(71) Applicant: NITTO DENKO CORPORATION, Ibaraki-shi, Osaka (JP)

(72) Inventors: Masaki MIZUTANI, Ibaraki-shi, Osaka (JP); Yuki HASEGAWA, Ibaraki-shi, Osaka (JP); Yusuke MOTEGI, Ibaraki-shi, Osaka (JP); Tsuyoshi CHIBA, Ibaraki-shi, Osaka (JP)

(73) Assignee: NITTO DENKO CORPORATION, Ibaraki-shi, Osaka (JP)

(21) Appl. No.: 14/646,426

(22) PCT Filed: Nov. 14, 2013
(86) PCT No.: PCT/JP2013/080777

§ 371 Date: May 21, 2015

(30) Foreign Application Priority Data
Dec. 10, 2012 (JP) 2012-269433

(51) Int. Cl. G02B 5/30; B32B 37/12; C09J 7/02; B32B 37/26; C09J 133/08; B32B 37/18; B32B 38/10

(52) U.S. Cl. CPC G02B 5/3033; B32B 37/18; B32B 37/12; B32B 38/10; B32B 37/26; C09J 133/08; C09J 7/0217; B32B 2037/268; B32B 2457/20; C09J 2433/003

(57) ABSTRACT

According to the invention, an optical film with adhesive on both sides comprises: an optical film including a polarizing plate; a first pressure sensitive adhesive layer provided on a surface of the optical film at a side configured to be bonded to an image display cell; and a second pressure sensitive adhesive layer provided on a surface of the optical film at a side configured to be bonded to a transparent plate or the touch panel. Further, a protective sheet is releasably attached on each of the first pressure sensitive adhesive layer and the second pressure sensitive adhesive layer. A thickness of the second pressure sensitive adhesive layer is preferably 30 μm or more. In a practical use, the optical film with adhesive on both sides according to the present invention is, for example, disposed between a front transparent plate or a touch panel and an image display cell.

### TECHNICAL FIELD

The present invention relates to an optical film with a pressure sensitive adhesive, which is used for formation of an image display device including a transparent plate or a touch panel on the front surface of an image display panel. Further, the present invention relates to a method for producing an image display device using the optical film with a pressure sensitive adhesive.

### BACKGROUND ART

Liquid crystal displays and organic EL displays are widely used as various kinds of image display devices of mobile phones, car navigation devices, personal computer monitors, televisions and so on. In the liquid crystal display device, a polarizing plate is disposed on a viewing side surface of an image display cell in accordance with the display principle of the liquid crystal display device. In the organic EL display device, a circularly polarizing plate (a laminate of a polarizing plate and a quarter wave plate) may be disposed on a viewing side surface of an image display cell for inhibiting external light reflection at a metal electrode (cathode) from being viewed like a mirror surface.

In a general image display device, a polarizing plate is disposed on the outermost surface of an image display panel (a liquid crystal panel or an organic EL panel). On the other hand, a front transparent plate (also referred to as a “window layer” etc.) such as a transparent resin plate or a glass plate may be provided on a viewing side of an image display panel for the purpose of, for example, preventing damage to the image display panel due to impact from the outer surface. In a display device including a touch panel, generally the touch panel is disposed on a viewing side of an image display panel (hereinafter, the front transparent plate and the touch panel may be referred to together as a “front transparent member”).

When a front transparent member such as a front transparent plate or a touch panel is disposed on a viewing side of an image display panel as described above, an air gap structure (hollow structure) with a gap of about 0.5 to 1.5 mm provided between these layers is formed for protecting the panel surface. However, since the refractive index of air in an air gap structure portion is about 1, whereas the refractive index of a plastic material or a glass material that forms a polarizing plate, a front transparent member and the like of an image display panel is about 1.5, reflection and refraction at an interface increase. Therefore, an image display device having an air gap structure has the problem that diffusion/scattering of image light emitted from an image display panel, and reflection of external light such as sunlight easily occur, leading to deterioration of visibility of the image display device.

For solving the above-mentioned problem, an “interlayer filling structure” has been recently proposed in which the air gap structure portion is filled with a transparent optical resin having a refractive index close to that of glass, resin and the like (see, for example, Patent Documents 1 and 2). In the interlayer filling structure, the air gap is filled with an optical resin to decrease a refractive index difference at the interface, and therefore deterioration of visibility due to reflection and scattering is suppressed. The air gap is filled with an optical resin to increase the strength of the whole image display device, and therefore even if a front transparent plate or the like is damaged, scattering of a constituent material thereof, such as glass, is prevented. Further, by using an adhesive as an optical resin that forms an interlayer filler, an image display panel and a front transparent member can be bonded and firmly fixed together.

An image display device that employs an interlayer filler configuration is generally prepared by a method in which a polarizing plate is bonded to a surface of an image display cell (liquid crystal cell, organic EL cell or the like) to prepare an image display panel, and the polarizing plate of the image display panel and a front transparent member are then bonded to each other with an interlayer filler interposed therebetween. For bonding the image display cell and the polarizing plate to each other, a pressure sensitive adhesive is generally used, and a method is widely used in which a polarizing plate with a pressure sensitive adhesive, in which a pressure sensitive adhesive layer is provided on one surface of the polarizing plate beforehand, is bonded to an image display cell.

Examples of the method for bonding a polarizing plate provided on a surface of an image display panel and a front transparent member to each other using an interlayer filler include a method using a liquid adhesive, and a method using a pressure sensitive adhesive. As the method using a liquid adhesive, a method is employed in which an appropriate amount of a liquid adhesive is applied onto an image display panel, a front transparent member is placed thereon, and an the liquid adhesive is wet-spread over the entire surface, and then polymerized/solidified by application of an ultraviolet ray, or the like. As the method using a pressure sensitive adhesive, a method is employed in which a pressure sensitive adhesive sheet is attached to one of a surface of a polarizing plate of an image display panel and a surface of a front transparent member, and the former surface and the latter surface are then bonded to each other using an appropriate method (see, for example, Patent Document 3).

### PRIOR ART DOCUMENTS

### Patent Documents

### Patent Document 1: Japanese Patent Laid-open Publication No. 2009-8851

### Patent Document 2: Japanese Patent Laid-open Publication No. 2008-281997

### Patent Document 3: Japanese Patent Laid-open Publication No. 2012-153788

### SUMMARY OF THE INVENTION

### Problems to be Solved by the Invention

The method using a liquid photocurable resin as an interlayer filler has a problem that contamination occurs due to protrusion of a liquid resin, and so on. On the other hand, the method using a pressure sensitive adhesive sheet is not satisfactory in workability because it is necessary that before bonding, a pressure sensitive adhesive sheet be cut so as to match the size of an image display device, and in addition, it is not easy to perform accurate bonding at a desired position.

The peripheral edge of a surface of a front transparent plate on the image display panel side is often subjected to printing for the purpose of decoration and light shielding. When the peripheral edge is subjected to printing, a level difference with a height of about 10 μm to several tens μm is generated at the boundary of the printed portion, and there may be the problem that bubbles are easily generated in the printing level difference portion when a sheet pressure sensitive adhesive is used as an interlayer filler.

### Means for Solving the Problems

The above-described problems related to bonding of an image display panel to a front member in an image display device employing an interlayer filling structure are solved by a polarizing plate with a pressure sensitive adhesive on both sides in which a pressure sensitive adhesive layer is provided on each of both surfaces of a polarizing plate.

The present invention relates to an optical film with a pressure sensitive adhesive on both sides, which is disposed between a front transparent plate or a touch panel and an image display cell. The optical film with a pressure sensitive adhesive on both sides according to the present invention includes a first pressure sensitive adhesive layer provided on a surface of an optical film including a polarizing plate at a side configured to be bonded to an image display cell, and includes a second pressure sensitive adhesive layer on a surface of the optical film at a side configured to be bonded to a transparent plate or a touch panel. A protective sheet is releasably attached on each of the first pressure sensitive adhesive layer and the second pressure sensitive adhesive layer. The thickness of the first pressure sensitive adhesive layer is preferably 3 to 30 μm, and the thickness of the second pressure sensitive adhesive layer is preferably 30 μm or more.

In one embodiment, the second pressure sensitive adhesive layer has a storage elastic modulus of 1.0×10⁴ Pa to 1.0×10⁷ Pa at 25° C., and a storage elastic modulus of 1.0×10² Pa to 1×10⁵ Pa at 80° C. The second pressure sensitive adhesive layer may contain a tackifier having a softening point of 50° C. to 150° C., so that the above temperature dependency of the storage elastic modulus is imparted. A pressure sensitive adhesive that forms the second pressure sensitive adhesive layer may include a base polymer containing a branched (meth)acrylic acid alkyl ester as a monomer unit, so that the above temperature dependency of the storage elastic modulus is imparted.

In one embodiment, the pressure sensitive adhesive that forms the second pressure sensitive adhesive layer is a photocurable pressure sensitive adhesive containing a photocurable monomer or a photocurable oligomer. In this embodiment, the second pressure sensitive adhesive layer preferably has a storage elastic modulus of 1.0×10³ Pa to 1.0×10⁶ Pa at 80° C. after being cured by application of an active ray.

The present invention also relates to a method for producing an image display device using the optical film optical film with a pressure sensitive adhesive on both sides. In the image display device, an optical film including a polarizing plate is disposed on an image display cell with a first pressure sensitive adhesive layer interposed therebetween, and a front transparent plate or a touch panel is disposed on the polarizing plate with a second pressure sensitive adhesive layer interposed therebetween.

The method for producing an image display device according to the present invention includes the following steps:

(1) First bonding step of peeling off a protective film attached on the first pressure sensitive adhesive layer of the optical film with a pressure sensitive adhesive on both sides, and then bonding the optical film and the image display cell to each other with the first pressure sensitive adhesive layer interposed therebetween; and

(2) Second bonding step of peeling off a protective sheet attached on the second pressure sensitive adhesive layer, and then bonding the optical film and the front transparent plate or the touch panel to each other with the second pressure sensitive adhesive layer interposed therebetween.

The first bonding step and the second bonding step may be sequentially performed in any order, or may be performed in parallel.

When the pressure sensitive adhesive that forms the second pressure sensitive adhesive layer is a photocurable pressure sensitive adhesive containing a photocurable monomer or a photocurable oligomer, it is preferred that after the second bonding step, an active ray is applied from the front transparent plate or touch panel to cure the second pressure sensitive adhesive.

### Effects of the Invention

An optical film with a pressure sensitive adhesive on both sides according to the present invention includes a first pressure sensitive adhesive layer for bonding the optical film to an image display cell, and a second pressure sensitive adhesive layer for bonding the optical film to a front transparent member such as a front transparent plate or a touch panel. According to this configuration, it is not necessary to provide an extra liquid adhesive or pressure sensitive adhesive sheet at the time when the image display panel and the front transparent member are bonded to each other to form an interlayer filling structure. Therefore, contamination due to protrusion of a liquid resin or a pressure sensitive adhesive sheet is prevented, and also the production process is simplified.

When the storage elastic modulus of the second pressure sensitive adhesive layer has a specific temperature dependency, the storage elastic modulus at or around 80° C. at the time of bonding the front transparent member can be reduced to impart level difference followability to the pressure sensitive adhesive, resulting in suppression of generation of bubbles. The storage elastic modulus at an operating environmental temperature of the image display device can be increased to suppress defects such as a position shift of the member during actual use and protrusion of the pressure sensitive adhesive.

Further, when the storage elastic modulus is increased by performing photocuring after bonding the optical film to the front transparent member while using a photocurable pressure sensitive adhesive as the second pressure sensitive adhesive layer, fluidization of the pressure sensitive adhesive is suppressed even if the image display device is exposed to a high-temperature environment. Therefore, generation of bubbles and peeling in the vicinity of the level difference can be suppressed.

### BRIEF DESCRIPTION OF THE DRAWINGS

FIG. 1 is a sectional view schematically showing one embodiment of an optical film with a pressure sensitive adhesive on both sides.

FIG. 2 is a sectional view schematically showing one embodiment of an optical film with a pressure sensitive adhesive on both sides.

FIG. 3 is a sectional view schematically showing one embodiment of an image display device.

FIG. 4 is a sectional view schematically showing one embodiment of an optical film with a pressure sensitive adhesive on both sides.

FIG. 5 is a sectional view schematically showing one embodiment of an optical film with a pressure sensitive adhesive on both sides.

### MODE FOR CARRYING OUT THE INVENTION

An optical film with a pressure sensitive adhesive on both sides according to the present invention includes a first pressure sensitive adhesive layer provided on one surface of an optical film including a polarizing plate, and includes a second pressure sensitive adhesive layer on the other surface. The first pressure sensitive adhesive layer is used for bonding an image display cell and the optical film to each other, and the second pressure sensitive adhesive layer is used for bonding a front transparent member (front transparent plate or touch panel) and the optical film to each other.

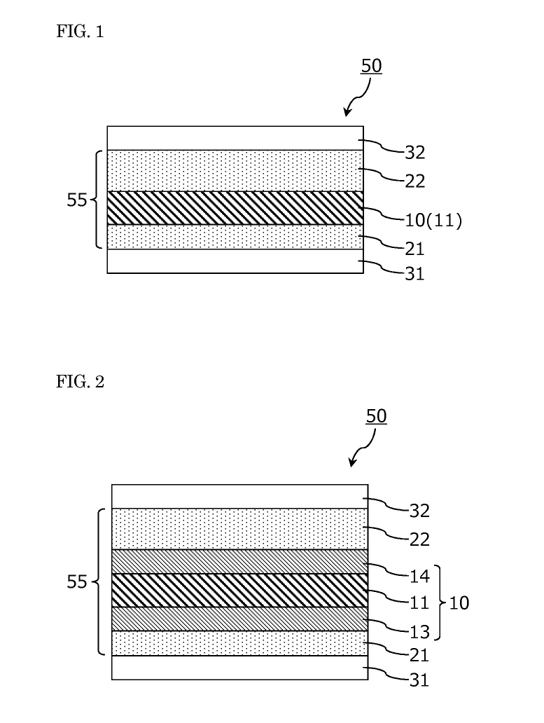

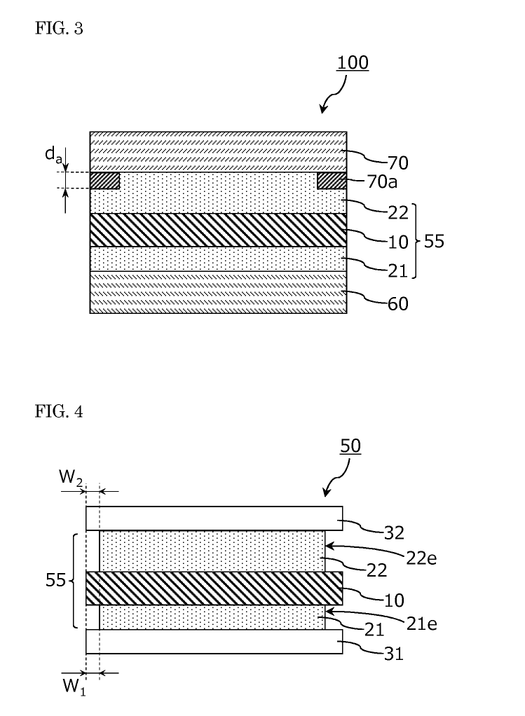

Hereinafter, the present invention will be described in detail with reference to the drawings. FIG. 1 is a sectional view schematically showing an optical film 50 with a pressure sensitive adhesive on both sides according to one embodiment of the present invention, and FIG. 3 is a sectional view schematically showing an image display device 100 according to one embodiment of the present invention.

The optical film 50 with a pressure sensitive adhesive on both sides as shown in FIG. 1 includes a polarizing plate 11 as the optical film 10. The optical film 50 with a pressure sensitive adhesive on both sides includes a first pressure sensitive adhesive layer 21 on one surface of the optical film 10, and a second pressure sensitive adhesive layer 22 on the other surface. A first protective sheet 31 is releasably attached on the first pressure sensitive adhesive layer 21, and a second protective sheet 32 is releasably attached on the second pressure sensitive adhesive layer 22.

In the image display device 100 shown in FIG. 3, one surface of the optical film 10 is bonded to an image display cell 60 with the first pressure sensitive adhesive layer 21 interposed therebetween, and the other surface of the optical film 10 is bonded to a front transparent member 70 with the second pressure sensitive adhesive layer 22 interposed therebetween.

[Optical Film]

As the polarizing plate 11 that forms the optical film 10, one having an appropriate transparent protective film laminated on one surface or both surfaces of a polarizer as necessary is generally used. The polarizer is not particularly limited, and various kinds of polarizers may be used. Examples of the polarizer include films obtained by impregnating a dichroic material such as iodine or a dichroic dye into a hydrophilic polymer film such as a polyvinyl alcohol-based film, a partially formalized polyvinyl alcohol-based film or an ethylene-vinyl acetate copolymer-based partially saponified film, and uniaxially stretching the film; and polyene-based oriented films such as those of dehydrated products of polyvinyl alcohol and dehydrochlorinated products of polyvinyl chloride.

For the transparent protective film as a protective film for the polarizer, a resin excellent in transparency, mechanical strength, thermal stability, moisture barrier property and optical isotropy, such as a cellulose-based resin, a cyclic polyolefin-based resin, an acryl-based resin, a phenylmaleimide-based resin or a polycarbonate-based resin, is preferably used. When a transparent protective film is provided on each of both surfaces of the polarizer, protective films formed of the same polymer material may be used or protective films formed of different polymer materials may be used on the front surface and the back surface. For the purpose of, for example, optical compensation and wide viewing of a liquid crystal cell, an optically anisotropic film such as a retardation sheet (stretched film) can also be used as a protective film for the polarizer.

As shown in FIG. 2, the optical film 10 may have other films 13 and 14 laminated on one surface or both surfaces of the polarizing plate 11 with an appropriate adhesive layer or a pressure sensitive adhesive layer (not illustrated) interposed therebetween as necessary. As the films 13 and 14, those that are used for formation of an image display device, such as retardation sheets, wide viewing films, viewing angle restriction (peep prevention) films and brightness enhancement films, are used, and the type thereof is not particularly limited.

For example, in the liquid crystal display device, an optical compensation film may be used as the film 13 between the image display cell (liquid crystal cell) 60 and the polarizing plate 11 for the purpose of, for example, improving viewing angle properties by appropriately changing the polarized state of light emitted from the liquid crystal cell to the viewing side.

In the organic EL display device, a quarter wave plate may be used as the film 13 for inhibiting external light from being reflected at a metal electrode layer to cause the surface to be viewed like a mirror surface. In such a configuration, the polarizing plate 11 and the quarter wave plate 13 are disposed so as to form a circularly polarizing plate. Typically, the polarizing plate 11 and the quarter wave plate 13 are disposed in a manner that an angle between the absorption axis direction of the polarizing plate 11 and the slow axis direction of the quarter wave plate 13 is substantially 45°.

The film 14 disposed on the polarizing plate 11 on the viewing side is a quarter wave plate or the like. For example, when the polarizing plate 11 and the quarter wave plate 14 are disposed in a manner that the absorption axis direction of the polarizing plate 11 and the slow axis direction of the quarter wave plate 14 form an angle of substantially 45°, linearly polarized light emitted from the polarizing plate 11 is converted into circularly polarized light by the quarter wave plate 14, so that a proper displayed image can be made visible even to a viewer wearing polarizing sunglasses.

A surface of the optical film 10 may be provided with a hard coat layer, or subjected to an antireflection treatment, or a treatment intended for prevention of sticking, diffusion or antiglare. A surface of the optical film 10 may be subjected to a surface modification treatment for the purpose of, for example, improving adhesiveness before the pressure sensitive adhesive layers 21 and 22 are provided thereon. Specific examples of the treatment include a corona treatment, a plasma treatment, a flame treatment, an ozone treatment, a primer treatment, a glow treatment, a saponification treatment, and a treatment with a coupling agent. An antistatic layer may also be formed.

[First Pressure Sensitive Adhesive Layer]

The first pressure sensitive adhesive layer 21 to be used for bonding the optical film to the image display cell 60 is provided on one surface of the optical film 10. The thickness of the first pressure sensitive adhesive layer 21 can be appropriately determined according to an intended use, adhesive strength and so on. The thickness is preferably 3 μm to 30 μm, more preferably 5 μm to 27 μm, further preferably 10 μm to 25 μm in the present invention. When the thickness of the first pressure sensitive adhesive layer falls within the above-mentioned range, excellent durability can be secured, and defects such as ingress of bubbles can be suppressed.

As the first pressure sensitive adhesive layer, a pressure sensitive adhesive containing as a base polymer an acryl-based polymer, a silicone-based polymer, a polyester, a polyurethane, a polyamide, a polyvinyl ether, a vinyl acetate/vinyl chloride copolymer, a modified polyolefin, an epoxy-based polymer, a fluorine-based polymer, or a polymer based on a rubber such as a natural rubber or a synthetic rubber can be appropriately selected and used. Particularly, an acryl-based pressure sensitive adhesive is preferably used because it is excellent in optical transparency, exhibits moderate wettability, cohesive strength and pressure sensitive adhesive properties such as adhesiveness, and is also excellent in weather resistance, heat resistance and the like.

The storage elastic modulus G′_{25° C.} of the first pressure sensitive adhesive layer 21 at 25° C. is preferably 1.0×10⁴ Pa to 1.0×10⁷ Pa. The storage elastic modulus G′_{25° C.} of the first pressure sensitive adhesive layer is more preferably 3.0×10⁴ Pa to 5.0×10⁶ Pa, further preferably 5.0×10⁴ Pa to 1.0×10⁶ Pa. The storage elastic modulus G′_{80° C.} of the first pressure sensitive adhesive layer 21 at 80° C. is preferably 5.0×10³ Pa to 5.0×10⁶ Pa, more preferably 1.0×10⁴ Pa to 1.0×10⁶ Pa. When the storage elastic modulus of the first pressure sensitive adhesive layer falls within the above-mentioned range, moderate adhesiveness is exhibited, and even when heating is performed for bonding the optical film 10 and the front transparent member 70 to each other with the second pressure sensitive adhesive layer 22 interposed therebetween, fluidization of the pressure sensitive adhesive is suppressed, so that problems such as glue contamination in which the pressure sensitive adhesive is stuck to other members are suppressed.

In this specification, the storage elastic modulus G′ is determined by reading a value at a predetermined temperature (25° C. or 80° C.) in measurement performed at a temperature elevation rate of 5° C./minute in a range of −50 to 150° C. under the condition of a frequency of 1 Hz in accordance with the method described in JIS K 7244-1 “Plastics-Determination of Dynamic Mechanical Properties”. The elastic modulus of a material exhibiting viscoelasticity, such as a pressure sensitive adhesive, can be represented by a storage elastic modulus G′ and a loss elastic modulus G″. In general, the loss elastic modulus G″ is an index indicating a degree of viscosity, while the storage elastic modulus G′ is used as an index indicating a degree of hardness.

When the storage elastic modulus of the first pressure sensitive adhesive is excessively small, defects such as protrusion of the pressure sensitive adhesive layer from the end surface may occur, for example, at the time of bonding the optical film 10 and the image display cell 60 to each other because the pressure sensitive adhesive layer is soft. On the other hand, when the storage elastic modulus is excessively large, adhesiveness tends to be reduced.

When an image display device is formed using the optical film with a pressure sensitive adhesive according to the present invention, the optical film is bonded to the image display cell 60, and the optical film is bonded to the front transparent member 70 such as a touch panel or a front transparent plate. The first pressure sensitive adhesive layer 21 is pressurized by a laminator or the like at the time of bonding the image display cell and the optical film 10 to each other, and also pressurized at the time of bonding the optical film 10 and the front transparent member 70 to each other. Generally, bonding of the front transparent member to the optical film 10 disposed on the surface of the image display panel is performed in a heating environment at around 80° C., and therefore in the present invention, it is preferred that the first pressure sensitive adhesive layer 21 has a storage elastic modulus in a specific range at 25° C. (at or around room temperature), and also has a storage elastic modulus in the above-mentioned range at 80° C. (heating environment).

[Second Pressure Sensitive Adhesive Layer]

The second pressure sensitive adhesive layer 22 to be used for bonding the optical film to the front transparent member 70 is provided on the other surface of the optical film 10. When an optical film with a pressure sensitive adhesive on both sides, in which the second pressure sensitive adhesive layer 22 for bonding the optical film to the front transparent member is provided on a surface opposite to the first pressure sensitive adhesive layer 21 to be used for bonding the optical film to the image display cell as described above, is used, it is not necessary to provide a step of providing a liquid adhesive or an extra sheet pressure sensitive adhesive layer on the optical film 10 in formation of an interlayer filling structure. Therefore, the production process of the image display device can be simplified, and contamination due to protrusion of an adhesive (pressure sensitive adhesive) is prevented.

<Thickness>

The thickness of the second pressure sensitive adhesive layer 22 is preferably 30 μm or more, more preferably 40 μm or more, further preferably 50 μm or more. When the thickness of the second pressure sensitive adhesive layer is below the above-mentioned range, ingress of bubbles tends to easily occur at the time of bonding the optical film and the front transparent member to each other.

Particularly, when a printed portion 70a is provided on the peripheral edge of a surface of the front transparent member 70 on the image display panel 60 side as schematically shown in FIG. 3, ingress of bubbles tends to easily occur in the vicinity of the printed portion 70a because the pressure sensitive adhesive layer cannot follow a printing level difference when the thickness of the second pressure sensitive adhesive layer is small. Therefore, when the front transparent member 70 having a non-flat portion such as the printed portion 70a on a surface to be bonded to the optical film 10 is used, the ratio of the thickness of the second pressure sensitive adhesive layer to the thickness dₐ of the non-flat portion (printed portion) 70a is preferably 1.2 or more, more preferably 1.5 or more, further preferably 2.0 or more.

The upper limit of the thickness of the second pressure sensitive adhesive layer 22 is not particularly limited, but is preferably 300 μm or less, further preferably 250 μm or less from the viewpoint of lightening/thinning of the image display device and in view of ease of forming the pressure sensitive adhesive layer, and handing characteristics.

<Storage Elastic Modulus>

The storage elastic modulus G′_{25° C.} of the second pressure sensitive adhesive layer 22 at 25° C. is preferably 1.0×10⁴ Pa to 1.0×10⁷ Pa. The storage elastic modulus G′_{25° C.}. of the second pressure sensitive adhesive layer is more preferably 3.0×10⁴ Pa to 7.0×10⁶ Pa, further preferably 5.0×10⁴ Pa to 5.0×10⁶ Pa.

When the storage elastic modulus at 25° C. is excessively small, the pressure sensitive adhesive protrudes from the end surface of the optical film under pressure at the time of cutting the optical film with a pressure sensitive adhesive to a desired size or at the time of bonding, so that the pressure sensitive adhesive tends to be easily stuck to a cut surface of the optical film, a cut blade or the like. On the other hand, when the storage elastic modulus at 25° C. is excessively large, cracking and chipping tend to easily occur at the end surface (cut surface) of the pressure sensitive adhesive during or after cutting. Particularly, the second pressure sensitive adhesive layer 22 has a thickness larger than that of the first pressure sensitive adhesive layer 21, so that sticking of the pressure sensitive adhesive layer to the cut blade, and cracking/chipping in the pressure sensitive adhesive tend to easily occur. Therefore, in the present invention, it is preferred that particularly the storage elastic modulus G′_{25° C.} of the second pressure sensitive adhesive layer 22 falls within the above-mentioned range. When the storage elastic modulus G′_{25° C.} of the second pressure sensitive adhesive layer falls within the above-mentioned range, the pressure sensitive adhesive layer can retain cohesive strength required for processability, handing characteristics and so on, and secure initial pressure sensitive adhesiveness in bonding of the second pressure sensitive adhesive layer 22 to the front transparent member 70.

The storage elastic modulus G′_{80° C.} of the second pressure sensitive adhesive layer 22 at 80° C. is preferably 1.0×10² Pa to 1.0×10⁵ Pa. When the storage elastic modulus G′_{80° C.} of the second pressure sensitive adhesive layer 22 falls within the above-mentioned range, protrusion from the end of the pressure sensitive adhesive layer at the time of bonding is suppressed, and ingress of bubbles is suppressed.

When the optical film such as a polarizing plate is bonded to the image display cell, ingress of bubbles can be suppressed by performing bonding while curving the optical film along a roll or the like. On the other hand, when the front transparent member such as a touch panel or a front transparent plate is bonded onto the image display panel with the pressure sensitive adhesive layer interposed therebetween, ingress of bubbles easily occurs because none of the image display panel and the front transparent member has flexibility, and therefore they cannot be bonded while being curved. When a non-flat portion such as the printed portion 70a exists in the front transparent member 70, ingress of bubbles tend to easily occur with the non-flat portion, or a level difference portion that is a boundary thereof, as an origination point. Therefore, when the touch panel, the front transparent plate or the like is bonded onto the image display panel with the pressure sensitive adhesive layer interposed therebetween, it is preferred that bonding is performed under reduced pressure and heating for the purpose of removing bubbles associated with bonding. After bonding, it is preferred that a pressurization/heating treatment is performed through autoclave or the like for suppressing generation of bubbles (delay bubbles).

When the storage elastic modulus G′_{80° C.} of the second pressure sensitive adhesive layer 22 at 80° C. is 1.0×10⁵ Pa or less, the storage elastic modulus of the pressure sensitive adhesive in the heating treatment is small (in other words, the pressure sensitive adhesive is soft), and therefore the shape of the pressure sensitive adhesive follows a level difference, an elevation and the like in the printed portion 70a or the like, so that ingress of bubbles is suppressed. Further, bubbles in the vicinity of the level difference, which are generated at the time of bonding at normal temperature, can be effectively removed. For effectively removing bubbles during heating, the storage elastic modulus G′_{800° C.} of the second pressure sensitive adhesive layer 22 is preferably 5.0×10⁴ Pa or less, more preferably 3.0×10⁴ Pa or less, further preferably 1.0×10⁴ Pa or less.

On the other hand, when the storage elastic modulus G′_{25° C.} of the second pressure sensitive adhesive layer 22 at 25° C. is small as described above, protrusion of the pressure sensitive adhesive from the end surface is apt to be significant. Therefore, it is preferred that G′_{25° C.} of the second pressure sensitive adhesive layer is 1.0×10⁴ Pa or more, more preferably 5.0×10⁴ Pa or more, further preferably 1.0×10⁵ Pa or more, and the storage elastic modulus G′80° C. of the second pressure sensitive adhesive layer falls within the above-mentioned range. That is, it is preferred that the second pressure sensitive adhesive layer has the storage elastic modulus G′ having a specific temperature dependency. The ratio of the storage elastic modulus G′_{25° C.} of the second pressure sensitive adhesive layer at 25° C. to the storage elastic modulus G′80° C. of the second pressure sensitive adhesive layer at 80° C.: G′_{25° C.}/G′_{80° C.} is preferably 5 or more, more preferably 10 or more, further preferably 20 or more, especially preferably 50 or more. The upper limit of the ratio G′_{25° C.}/G′_{80° C.} is not particularly limited, but generally is preferably 1000 or less, further preferably 500 or less in view of pressure sensitive adhesiveness at the time of bonding at normal temperature.

Examples of the method for causing the pressure sensitive adhesive layer to have the temperature dependency include a method using a copolymer containing a branched (meth)acrylic acid alkyl ester as a monomer unit in a base polymer of a pressure sensitive adhesive that forms the pressure sensitive adhesive layer. The pressure sensitive adhesive layer can also be caused to have an intended temperature dependency using, for example, a method in which a component having a softening point of about 50° C. to 150° C. is added in the pressure sensitive adhesive layer.

Further, in the optical film with a pressure sensitive adhesive on both sides according to the present invention, the storage elastic modulus G′80° C. of the second pressure sensitive adhesive layer 22 at 80° C. is preferably 1.0×10³ Pa to 1.0×10⁶ Pa after the optical film 10 is bonded to the front transparent member 70 with the second pressure sensitive adhesive layer 22 interposed therebetween to form the image display device. When the storage elastic modulus G′_{80° C.}of the second pressure sensitive adhesive layer 22 after formation of the image display device falls within the above-mentioned range, fluidization of the pressure sensitive adhesive layer is suppressed even if it is exposed to a heating environment in actual use of the image display device. Therefore, defects such as regeneration of bubbles (delay bubbles) and peeling of the pressure sensitive adhesive layer are suppressed, so that long-term-reliable adhesiveness can be achieved.

As a method for increasing the storage elastic modulus G′_{80° C.} after formation of the image display device as compared to the storage elastic modulus G′_{80° C.} at the time of bonding as described above, it is preferred to use a photocurable or thermosetting pressure sensitive adhesive as the pressure sensitive adhesive that forms the second pressure sensitive adhesive layer 22. In this case, the second pressure sensitive adhesive layer 22 has moderate adhesiveness and fluidity at the time of bonding the optical film to the front transparent member. When the pressure sensitive adhesive is cured by application of an active ray or heating at the time of bonding or after a heating treatment is performed in an autoclave, the storage elastic modulus of the second pressure sensitive adhesive layer can be increased to suppress defects such as peeling of the pressure sensitive adhesive layer.

Particularly, for achieving both adhesiveness and fluidity at the time of bonding and reliability of adhesion after formation of the image display device, the storage elastic modulus G′_{80° C.} of the second pressure sensitive adhesive layer 22 at 80° C. after curing is preferably 1.0×10³ Pa to 1.0×10⁶ Pa, more preferably 3.0×10³ Pa to 7.0×10⁵ Pa, further preferably 5.0×10³ Pa to 5.0×10⁵ Pa. For achieving both adhesiveness and fluidity at the time of bonding and adhesion reliability after formation of the image display device, the ratio of the storage elastic modulus G′_{80° C.} of the second pressure sensitive adhesive layer after curing to the storage elastic modulus G′_{80° C.} of the second pressure sensitive adhesive layer before curing is preferably 2 or more, more preferably 3 or more, further preferably 5 or more.

<Composition>

The composition of the pressure sensitive adhesive that forms the second pressure sensitive adhesive layer 22 is not particularly limited, and one containing as a base polymer an acryl-based polymer, a silicone-based polymer, a polyester, a polyurethane, a polyamide, a polyvinyl ether, a vinyl acetate/vinyl chloride copolymer, a modified polyolefin, an epoxy-based polymer, a fluorine-based polymer, or a polymer based on a rubber such as a natural rubber or a synthetic rubber can be appropriately selected and used. Particularly, an acryl-based pressure sensitive adhesive containing an acryl-based polymer as a base polymer is preferably used because it is excellent in optical transparency and adhesiveness, and the storage elastic modulus is adjusted to fall within the above-mentioned range.

As the acryl-based polymer, one having a monomer unit of a (meth)acrylic acid alkyl ester as a main skeleton is suitably used. In this specification, the “(math)acryl” means acryl and/or methacryl.

As the (meth)acrylic acid alkyl ester, a (meth)acrylic acid alkyl ester with the alkyl group having 1 to 20 carbon atoms is preferably used. Examples of the (meth)acrylic acid alkyl ester include methyl (meth)acrylate, ethyl (meth)acrylate, butyl (meth)acrylate, isobutyl (meth)acrylate, s-butyl (meth)acrylate, t-butyl (meth)acrylate, pentyl (meth)acrylate, isopentyl (meth)acrylate, neopentyl (meth)acrylate, hexyl (meth)acrylate, heptyl (meth)acrylate, 2-ethylhexyl (meth)acrylate, octyl (meth)acrylate, isooctyl (meth)acrylate, nonyl (meth)acrylate, isononyl (meth)acrylate, decyl (meth)acrylate, isodecyl (meth)acrylate, undecyl (meth)acrylate, dodecyl (meth)acrylate, isotridodecyl (meth)acrylate, tetradecyl (meth)acrylate, isotetradecyl (meth)acrylate, pentadecyl (meth)acrylate, cetyl (meth)acrylate, heptadecyl (meth)acrylate, octadecyl (meth)acrylate, isooctadecyl (meth)acrylate, nonadecyl (meth)acrylate and alakyl (meth)acrylate.

The content of the (meth)acrylic acid alkyl ester is preferably 40% by weight or more, more preferably 50% by weight or more, further preferably 60% by weight or more based on the total amount of monomer components that form the base polymer.

The acryl-based base polymer may be a copolymer of a plurality of (meth)acrylic acid alkyl esters. The arrangement of constituent monomer units may be random, or blockwise. It is preferred that the acryl-based base polymer contains a (meth)acrylic acid alkyl ester having a branched alkyl group as the (meth)acrylic acid alkyl ester for the purpose of, for example, causing the storage elastic modulus of the second pressure sensitive adhesive layer 22 to have a desired temperature dependency. Among the monomers shown above as an example, 2-ethylhexyl (meth)acrylate, isooctyl (meth)acrylate, isononyl (meth)acrylate, isodecyl (meth)acrylate, isotetradecyl (meth)acrylate, isooctadecyl (meth)acrylate and so on are suitably used as the branched alkyl (meth)acrylic acid ester. Two or more branched alkyl (meth)acrylic acid esters may be used in combination. These branched (meth)acrylic acid alkyl esters may be used in combination with a linear (meth)acrylic acid ester. When a branched monomer is used as a monomer unit of a copolymer, the elastic modulus of the pressure sensitive adhesive in a flat region (high-temperature environment) tends to decrease, so that an appropriate temperature dependency of the storage elastic modulus is imparted.

The acryl-based base polymer may contain as a copolymer component an acryl-based monomer unit having a crosslinkable functional group. Examples of the acryl-based monomer having a crosslinkable functional group include hydroxyl group-containing monomers and carboxyl group-containing monomers. Particularly, it is preferred that a hydroxyl group-containing monomer is contained as the copolymer component of the base polymer.

Examples of the hydroxyl group-containing monomer include 2-hydroxyethyl (meth)acrylate, 2-hydroxypropyl (meth)acrylate, 4-hydroxybutyl (meth)acrylate, 6-hydroxyhexyl (meth)acrylate, 8-hydroxyoctyl (meth)acrylate, 10-hydroxydecyl (meth)acrylate, 12-hydroxylauryl (meth)acrylate and (4-hydroxymethylcyclohexyl)-methyl acrylate. Examples of the carboxyl group-containing monomer include (meth)acrylic acids, carboxyethyl (meth)acrylate, carboxypentyl (meth)acrylate, itaconic acid, maleic acid, fumaric acid and crotonic acid.

Besides the above-described compounds, acid anhydride group-containing monomers, caprolactone adducts of acrylic acids, sulfonic acid group-containing monomers and phosphoric acid group-containing monomers can be used as the copolymerization monomer component. As the modifying monomer, vinyl-based monomers such as vinyl acetate, vinyl propionate, N-vinylpyrrolidone, methylvinylpyrrolidone, vinylpyridine, vinylpiperidone, vinylpyrimidine, vinylpiperazine, vinylpyrazine, vinylpyrrole, vinylimidazole, vinyloxazole, vinylmorpholine, N-vinylcarboxylic acid amides, styrene, α-methylstyrene and N-vinylcaprolactam; cyano acrylate-based monomers such as acrylonitrile and methacrylonitrile; epoxy group-containing acryl-based monomers such as glycidyl (meth)acrylate; glycol-based acryl ester monomers such as polyethylene glycol (meth)acrylate, polypropylene glycol (meth)acrylate, methoxyethylene glycol (meth)acrylate and methoxypolypropylene glycol (meth)acrylate; and acrylic acid ester-based monomers such as tetrahydrofurfuryl (meth)acrylate, fluorine (meth)acrylate, silicone (meth)acrylate and 2-methoxyethyl acrylate can also be used.

The ratio of the copolymerizable monomer component in the acryl-based polymer is not particularly limited, but when a hydroxyl group-containing monomer is used as a copolymerizable monomer component for the purpose of, for example, introducing a crosslinking point, the content is preferably about 3 to 50%, more preferably about 5 to 30% based on the weight ratio of total constituent monomers.

The storage elastic modulus of the pressure sensitive adhesive can be adjusted by appropriately changing the types, molecular weights and blending ratios (copolymerization ratios) of monomers that form the base polymer, and the molecular weight (polymerization degree) of the base polymer. Generally, when the molecular weight of the base polymer is increased, the storage elastic modulus tends to increase. When an ethylenically unsaturated monomer having an acidic group is used as the copolymerizable monomer, the storage elastic modulus tends to increase. On the other hand, when the amount of a (meth)acrylate monomer having a carbonyl group in alcohol residues, the storage elastic modulus tends to decrease.

The acryl-based polymer as a base polymer is obtained by polymerizing the monomer components using various kinds of known methods such as solution polymerization, emulsification polymerization and mass polymerization. The solution polymerization method is suitable from the viewpoint of a balance of properties such as adhesive strength and retentive strength of the pressure sensitive adhesive, costs and so on. As a solvent for solution polymerization, ethyl acetate, toluene or the like is generally used. The solution concentration is normally about 20 to 80% by weight. As a polymerization initiator, any of various kinds of known polymerization initiators such as azo-based and peroxide-based polymerization initiators can be used. For adjusting the molecular weight, a chain-transfer agent may be used. The reaction temperature is normally about 50 to 80° C., and the reaction time is normally about 1 to 8 hours.

The molecular weight of the base polymer is appropriately adjusted so that the second pressure sensitive adhesive layer 22 has an intended storage elastic modulus. For example, the polystyrene-equivalent weight average molecular weight is about 50000 to 2000000, preferably about 70000 to 1800000.

The second pressure sensitive adhesive layer 22 may have a crosslinked structure as necessary. The crosslinked structure is formed by, for example, adding a crosslinker after polymerization of the base polymer. As the crosslinker, a common cross linker can be used, such as an isocyanate-based crosslinker, an epoxy-based crosslinker, an oxazoline-based crosslinker, an aziridine-based crosslinker, a carbodiimide-based crosslinker or a metal chelate-based crosslinker. The crosslinker can form a crosslinked structure by reacting with a functional group such as a hydroxyl group introduced into the base polymer.

The content of the crosslinker is normally 10 parts by weight or less, preferably parts by weight or less based on 100 parts by weight of the acryl-based base polymer. When the added amount of the crosslinker is excessively large, the flexibility of the pressure sensitive adhesive may be reduced, leading to a reduction in adherence to an adherend. When a crosslinker is used as a pressure sensitive adhesive composition, it is preferred to pass through a heating step for forming a crosslinked structure. The heating temperature and the heating time are appropriately set according to a type of crosslinker to be used, and crosslinking is normally performed by heating at 20° C. to 160° C. for 1 minute to about 7 days.

A silane coupling agent can also be added in the pressure sensitive adhesive layer for the purpose of adjusting the adhesive strength. As the silane coupling agent, for example, vinyltriethoxysilane, vinyltris(β-methoxyethoxy)silane, γ-methacryloxypropyltrimethoxysilane, vinyltriacetoxysilane, γ-glycidoxypropyltrimethoxysilane, γ-glycidoxypropyltriethoxysilane, β-(3,4-epoxycyclohexyl)ethyltrimethoxysilane, γ-chloropropylmethoxysilane, vinyltrichlorosilane, γ-mercaptopropyltrimethoxysilane, γ-aminopropyltriethoxysilane, N-β (aminoethyl)-γ-aminopropyltrimethoxysilane and the like can be used alone, or in combination of two or more thereof. When a silane coupling agent is added to the pressure sensitive adhesive, the added amount thereof is normally about 0.01 to 5.0 parts by weight, preferably 0.03 to 2.0 parts by weight based on 100 parts by weight of the acryl-based base polymer.

In the pressure sensitive adhesive layer, a tackifier can be used as necessary. As the tackifier, for example, a terpene-based tackifier, a styrene-based tackifier, a phenol-based tackifier, a rosin-based tackifier, an epoxy-based tackifier, a dicyclopentadiene-based tackifier, a polyamide-based tackifier, a ketone-based tackifier, an elastomer-based tackifier or the like can be used.

The tackifier can also contribute to impartation of a temperature dependency to the storage elastic modulus of the pressure sensitive adhesive. For imparting an intended temperature dependency to the storage elastic modulus of the second pressure sensitive adhesive layer 22, the softening point of the tackifier is preferably about 50° C. to 150° C., more preferably about 70° C. to 140° C. The softening point can be measured in accordance with JIS K 2207 “Ring and Ball Softening Point Method”.

A tackifier having a weight average molecular weight of about 200 to 5000, preferably about 500 to 3000 is suitably used so that the tackifier has a softening point in the above-mentioned range and compatibility with the acryl-based base polymer. When a hydrocarbon resin such as a terpene-based tackifier, a rosin-based tackifier, a dicyclopentadiene-based tackifier or a phenol-based tackifier is used as the tackifier, it is preferred to use a hydrogen-added (hydrogenated) tackifier for improving compatibility with the acryl-based pressure sensitive adhesive and securing transparency. As a styrene-based tackifier, one that is partially or fully hydrogenated can also be used.

Among the tackifiers described above, a hydrogenated terpene phenolic resin is suitably used from the viewpoint of compatibility with the acryl-based base polymer and impartation of a temperature dependency to the storage elastic modulus. As a commercial product of the hydrogenated terpene phenolic resin, “YS Polyster NH” (product name) manufactured by Yasuhara Chemical Co., LTD, or the like can be used.

When the second pressure sensitive adhesive layer 22 contains a tackifier, the content thereof is preferably 5 to 300 parts by weight, more preferably 10 to 150 parts by weight based on 100 parts by weight of the acryl-based base polymer. When the content of the tackifier is excessively large, the pressure sensitive adhesive may be cracked, or the storage elastic modulus at 80° C. may excessively decrease.

As described above, in one embodiment of the present invention, the pressure sensitive adhesive that forms the second pressure sensitive adhesive layer 22 is preferably a photocurable or thermosetting pressure sensitive adhesive. The photocurable or thermosetting pressure sensitive adhesive contains a photocurable or thermosetting monomer, or a photocurable or thermosetting oligomer in addition to the above-mentioned base polymer, crosslinker and tackifier. When a photocurable or thermosetting pressure sensitive adhesive is used for the second pressure sensitive adhesive layer 22, the storage elastic modulus can be increased by curing the second pressure sensitive adhesive layer 22 after bonding the optical film 10 and the front transparent member 70 to each other with the second pressure sensitive adhesive layer 22 interposed therebetween. Therefore, even when the image display device is exposed to a high-temperature environment, fluidization of the pressure sensitive adhesive is suppressed, so that generation of bubbles and peeling hardly occur. Thus long-term-reliable adhesiveness can be achieved.

A photocurable pressure sensitive adhesive is especially suitably used from the viewpoint of controlling timing of curing, reliability and so on. The method of photocuring is preferably a method in which a system containing a photocurable monomer or a photocurable oligomer and a photoradical generator is irradiated with an active ray such as an ultraviolet ray. A system using an ethylenically unsaturated compound and a photoradical generator is preferred because it has a high level of photosensitivity and can be selected from a wide range of materials.

The photocurable ethylenically unsaturated compound may be a monofunctional compound, or may be a polyfunctional compound. Examples of the monofunctional ethylenically unsaturated compound may include 2-ethylhexyl (meth)acrylate, n-butyl (meth)acrylate, i-butyl (meth)acrylate, t-butyl (meth)acrylate, lauryl (meth)acrylate, alkyl (meth)acrylates, methoxyethyl (meth)acrylate, 2-hydroxyethyl (meth)acrylate, 2-hydroxypropyl (meth)acrylate, 2-hydroxybutyl (meth)acrylate, benzyl (meth)acrylate, phenyl (meth)acrylate, ethylene glycol di(meth)acrylate, diethylene glycol di(meth)acrylate, triethylene glycol di(meth)acrylate, hydroxyethyl (meth)acrylate, 1,3-butylene glycol di(meth)acrylate, 1,4-butylene glycol di(meth)acrylate, neopentyl glycol di(meth)acrylate, 1,6-hexanediol di(meth)acrylate, dicyclopentenyloxyethyl (meth)acrylate and norbornene (meth)acrylate. Examples of the monofunctional ethylenically unsaturated compound include, in addition to the above-mentioned compounds, (meth)acrylate phenoxyethyl (meth)acrylate (PO), phenoxy polyethylene glycol (meth)acrylate, 2-hydroxy-3-phenoxypropyl (meth)acrylate, cyclohexyl (meth)acrylate (CH), nonylphenol EO adduct (meth)acrylate, methoxytriethylene glycol (meth)acrylate, tetrahydrofurfuryl (meth)acrylate and 2-hydroxy-3-phenoxypropyl acrylate.

Examples of the polyfunctional ethylenically unsaturated compound include polyethylene glycol di(meth)acrylate, polypropylene glycol di(meth)acrylate, polytetramethylene glycol di(meth)acrylate, bisphenol A ethylene oxide-modified di(meth)acrylate, bisphenol A propylene oxide-modified (meth)acrylate, alkanediol di(meth)acrylate, tricyclodecane dimethanol di(meth)acrylate, ethoxylated isocyanuric acid triacrylate, pentaerythritol tri(meth)acrylate, pentaerythritol di(meth)acrylate, trimethylolpropane tri(meth)acrylate, ditrimethylolpropane tetra(meth)acrylate, ethoxylated pentaerythritol tetra(meth)acrylate, pentaerythritol tetra(meth)acrylate, dipentaerythritol poly(meth)acrylate, dipentaerythritol hexa(meth)acrylate, neopentyl glycol di(meth)acrylate, glycerin di(meth)acrylate, urethane (meth)acrylate, epoxy (meth)acrylate, butadiene (meth)acrylate and isoprene (meth)acrylate.

Preferably, the photocurable compound is contained in the pressure sensitive adhesive as a monomer or an oligomer. The photocurable monomers or oligomers may be used in combination of two or more thereof. When the second pressure sensitive adhesive layer 22 is formed of a photocurable pressure sensitive adhesive, a monomer component that forms the base polymer of the pressure sensitive adhesive layer, or a compound similar to the crosslinker may be used as the photocurable monomer component. The photocurable compound for forming the photocurable pressure sensitive adhesive is required to exist in the pressure sensitive adhesive as a monomer or an oligomer. Therefore, it is preferred that after polymerization of the base polymer, the base polymer is crosslinked as necessary, and a photocurable compound is then added in the system.

When the second pressure sensitive adhesive layer 22 is formed of a photocurable pressure sensitive adhesive, the content of the photocurable compound is preferably 2 to 50 parts by weight, more preferably 5 to 30 parts by weight based on 100 parts by weight of the whole pressure sensitive adhesive composition. When the content of the photocurable compound (monomer and/or oligomer) falls within the above-mentioned range, the elastic modulus before and after curing can be adjusted to fall within a preferred range. When the content of the photocurable compound is excessively large, the storage elastic modulus of the pressure sensitive adhesive layer before curing decreases, so that defects may occur at the time of cutting and bonding the optical film.

When the second pressure sensitive adhesive layer 22 is a photocurable pressure sensitive adhesive, it is preferred that the pressure sensitive adhesive layer contains a photoradical generator. As the photoradical generator, a compound having one or more radical generation points in the molecule is used, and examples thereof include hydroxyketones, benzyl dimethyl ketals, aminoketones, acylphosphine oxides, benzophenones and trichloromethyl-containing triazine derivatives. The photoradical generators may be used alone, or may be used in combination of two or more thereof. A monofunctional type photoradical generator and a polyfunctional type photoradical generator may be used in combination as appropriate.

When the second pressure sensitive adhesive layer 22 is formed of a photocurable pressure sensitive adhesive, the content of the photoradical generator is preferably 0.01 to 10 parts by weight, more preferably 0.05 to 8 parts by weight based on 100 parts by weight of the whole pressure sensitive adhesive composition.

In addition to the components shown above as an example, additives such as a plasticizer, a softener, a degradation inhibitor, a filler, a colorant, an ultraviolet ray absorber, an antioxidant, a surfactant and an antistatic agent can be used in the pressure sensitive adhesive layer within the bounds of not impairing the feature of the present invention.

[Formation of Pressure Sensitive Adhesive Layer on Optical Film]

Examples of the method for forming the first pressure sensitive adhesive layer 21 and the second pressure sensitive adhesive layer 22 on the optical film 10 include a method in which the pressure sensitive adhesive composition is applied to a separator etc. subjected to a release treatment, dried to remove a solvent etc., and subjected to a crosslinking treatment as necessary to form a pressure sensitive adhesive layer, and the pressure sensitive adhesive layer is then transferred onto the optical film 10; and a method in which the pressure sensitive adhesive composition is applied to the optical film 10, and dried to remove a solvent etc., so that a pressure sensitive adhesive layer is formed on the optical film.

As the method for forming the pressure sensitive adhesive layer, various kinds of methods are used. Specific examples include roll coating, kiss roll coating, gravure coating, reverse coating, roll brushing, spray coating, dip roll coating, bar coating, knife coating, air knife coating, curtain coating, lip coating, and extrusion coating methods using a die coater etc. Among them, use of a die coater is preferred, and in particular, use of a die coater using a fountain die or a slot die is more preferred.

As a method for drying the applied pressure sensitive adhesive, a suitable method can be appropriately employed according to a purpose. The heating/drying temperature is preferably 40° C. to 200° C., more preferably 50° C. to 180° C., further preferably 70° C. to 170° C. The drying time is preferably 5 seconds to 20 minutes, more preferably 5 seconds to 15 minutes, further preferably 10 seconds to 10 minutes.

[Protective Sheet]

Protective sheets 31 and 32 are releasably attached to the first pressure sensitive adhesive layer 21 and the second pressure sensitive adhesive layer 22, respectively. The protective sheets 31 and 32 are used for the purpose of protecting the exposed surfaces of the pressure sensitive adhesive layers 21 and 22 until an optical film with a pressure sensitive adhesive 55 is put into practical use, and bonded to the image display cell 60 and the front transparent member 70.

Examples of the constituent material of each of the protective sheets 31 and 32 include plastic films such as polyethylene, polypropylene, polyethylene terephthalate and polyester films, porous materials such as paper, cloth and nonwoven fabrics, and appropriate thin foliated materials such as nets, foamed sheets, metal foils and laminates thereof, and plastic films are suitably used because they are excellent in surface smoothness.

The plastic film is not particularly limited as long as it is a film capable of protecting the surface of the pressure sensitive adhesive layer, and examples thereof include polyethylene films, polypropylene films, polybutene films, polybutadiene films, polymethylpentene films, polyvinyl chloride films, vinyl chloride copolymer films, polyethylene terephthalate films, polybutylene terephthalate films, polyurethane films and ethylene-vinyl acetate copolymer films.

The thickness of each of the protective sheets 31 and 32 is normally 5 to 200 μm, preferably about 10 to 150 μm. The protective sheet may be subjected to release and antifouling treatments with a silicone-based, fluorine-based, long-chain alkyl-based or fatty acid amide-based releasing agent, a silica powder or the like, and an antistatic treatment of coating type, kneading type, vapor deposition type or the like. Particularly, by appropriately subjecting the surface of the protective sheet to a release treatment such as a silicone treatment, a long-chain alkyl treatment or a fluorine treatment, releasability from the pressure sensitive adhesive layers 21 and 22 can be further improved in practical use.

Separators etc. used for transferring the pressure sensitive adhesive layers 21 and 22 onto the optical film 10 can be used as the protective sheets 31 and 32 for the optical film with a pressure sensitive adhesive.

[Cutting]

The optical film with a pressure sensitive adhesive is put into practical use after being cut to a desired size as necessary. Generally, a long-shaped optical film with a pressure sensitive adhesive is cut to a product size consistent with a size (screen size) of an image display device. Examples of the cutting method include a method of punching the film using a Thompson blade etc., a method using a cutter with a circular shear, a plate blade or the like, and a method using laser light or hydraulic pressure.

In the optical film with a pressure sensitive adhesive, the surfaces of the pressure sensitive adhesive layers are protected because the protective sheets 31 and 32 are attached on the surfaces of the pressure sensitive adhesive layers 21 and 22. On the other hand, the side surface of the pressure sensitive adhesive layer is generally exposed to the outside. Therefore, defects may occur such as a phenomenon in which during cutting, transportation, handling and so on, the side surface of the pressure sensitive adhesive layer, which is exposed to the outside, comes into contact with some object, so that the pressure sensitive adhesive at the end falls to be missing (glue missing), and contamination of the surface of the optical film, or the like by the falling pressure sensitive adhesive (glue contamination). Particularly, when the second pressure sensitive adhesive layer 22 has a large thickness, the second pressure sensitive adhesive layer 22 is stuck to a cutting blade during cutting, and glue missing and glue contamination tend to easily occur.

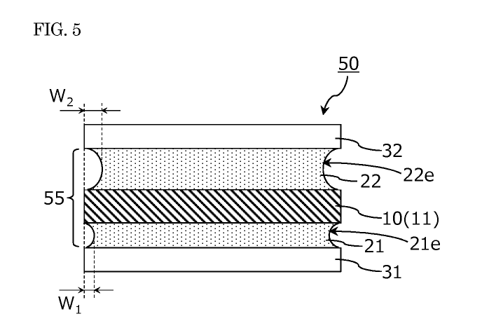

In one embodiment, an optical film with a pressure sensitive adhesive layer on both sides 100 has a configuration in which the side surface of at least one of the first pressure sensitive adhesive layer 21 and the second pressure sensitive adhesive layer 22 is located inner side than the side surface of the optical film 10, as schematically shown in FIGS. 4 and 5. Preferably, at least a part of side surfaces 21e and 22e of the first pressure sensitive adhesive layer 21 and/or the second pressure sensitive adhesive layer 22 is located inside the optical film 10, and also inside the protective sheets 31 and 32. When the side surface (end) of the pressure sensitive adhesive layer is located inner side than the side surfaces of the optical film and the protective sheet, glue contamination and glue missing during transportation and on the processing line for bonding to the image display cell, or the like are suppressed. In the present invention, it is preferred that particularly the side surface 22e of the second pressure sensitive adhesive layer 22 is located inside the optical film 10, and it is preferred that both the side surface 21e of the first pressure sensitive adhesive layer 21 and the side surface 22e of the second pressure sensitive adhesive layer 22 are located inside the optical film 10.

In the present invention, since the second pressure sensitive adhesive layer 22 has a large thickness, so that glue missing and glue contamination easily occur, it is preferred that at least a part of the side surface 22e of the second pressure sensitive adhesive layer 22 is located inner side than the side surface of the optical film 10, and further, it is preferred that at least a part of the side surface 22e of the second pressure sensitive adhesive layer 22 is located inner side than the side surface of the protective sheet 32. The part of the side surface 22e of the second pressure sensitive adhesive, which is located inner side than the side surface of the optical film 10, extends over preferably ½ or more, more preferably ¾ or more, especially preferably the whole of the length of the side periphery of the pressure sensitive adhesive layer 22. Preferably, the side surface 21e of the first pressure sensitive adhesive layer 21 is located inside the optical film 10 and/or the protective sheet 31 over ½ or more, more preferably ¾ or more, especially preferably the whole of the length of the side periphery similarly to the second pressure sensitive adhesive layer 22.

When the side surfaces 21e and 22e of the pressure sensitive adhesive layers 21 and 22 are located inner side than the side surface of the optical film 10 and/or the protective sheets 31 and 23, the cross-sectional shape of the pressure sensitive adhesive layer is generally a shape shown in, for example, FIG. 4. Alternatively, a configuration may be employed in which as shown in FIG. 5, the side surface of the pressure sensitive adhesive layer is almost coincident with the side surface of the optical film and/or the protective sheet in the vicinity of the interface between the pressure sensitive adhesive layers 21 and 22 and the optical film 10 and/or the protective sheets 31 and 32, and is located inner side than the side surface of the optical film and/or the protective sheet in the vicinity of the central part of the pressure sensitive adhesive layer in the thickness direction. Presence/absence and the shape of a part of the side surface of the pressure sensitive adhesive layer, which is located inside the optical film and/or the protective sheet, are not limited to those described above, and may be appropriately set.

Examples of the method for situating the side surface of the pressure sensitive adhesive layer inside the side surface of the optical film and the side surface of the protective sheet include a method in which the area of pressure sensitive adhesive layer provided on the optical film is controlled, and a method in which after the pressure sensitive adhesive layer is provided, only a pressure sensitive adhesive layer part is removed.

As an especially preferred method, mention is made of a method in which the protective sheets 31 and 32 are attached onto the pressure sensitive adhesive layers 21 and 22, the optical film with a pressure sensitive adhesive on both sides is then pressurized from above the protective sheets 31 and 32 to cause the end of the pressure sensitive adhesive layer to protrude from the end of the optical film, and the pressure sensitive adhesive layer is cut together with the optical film 10 and the protective sheets 31 and 32 with the pressure sensitive adhesive layer protruding from the end of the optical film. When the pressure is released after cutting, the side surfaces 21e and 22e of the pressure sensitive adhesive layers 21 and 21 can be forced backward to inside the side surface of the optical film 10 and/or the protective sheets 31 and 32. In this case, for example, a method is preferably used in which a long-shaped optical film is punched with a Thompson blade etc., a plurality of punched optical films with a pressure sensitive adhesive are then stacked on one another, and pressurized in the stacking direction, and the inside of a cut surface obtained by punching is cut (trimmed) using a rotary blade etc. with the pressure sensitive adhesive layer protruding from the side surface, so that the optical film is fabricated to a product size.

Distances (longest parts) W₁ and W₂ between parts of the side surfaces of the pressure sensitive adhesive layers 21 and 22, which are located inner side than the side surface of the optical film 10, and the side surface of the optical film are preferably about 10 μm to 300 μm, more preferably about 20 μm to 250 μm, further preferably about 30 μm to 200 μm for preventing occurrence of defects in image display and bonding while suppressing glue missing and glue contamination. In the case of the method in which the pressure sensitive adhesive layer is cut together with the optical film and the protective sheet under pressure, and the pressure is then released, the distance W can be made to fall within a desired range by adjusting the pressure applied to the pressure sensitive adhesive layer and the elastic modulus of the pressure sensitive adhesive layer. The distances W1 and W2 may be the same, or may be different.

[Image Display Device]

The optical film with a pressure sensitive adhesive on both sides according to the present invention is suitably used for formation of the image display device 100 which includes the image display cell 60 such as a liquid crystal cell or an organic EL cell on one surface of the optical film 10 including a polarizing plate, and includes the front transparent member 70 such as a touch panel or a front transparent plate on the other surface (viewing side) as schematically shown in FIG. 3. In the image display device, the image display cell 60 is bonded to the optical film 10 with the first pressure sensitive adhesive layer 21 interposed therebetween, and the front transparent member 70 is bonded to the optical film 10 with the second pressure sensitive adhesive layer 22 interposed therebetween.

The front transparent member 70 is, for example, a front transparent plate (window layer) or a touch panel. As the front transparent plate, a transparent plate having appropriate mechanical strength and thickness. As this transparent plate, for example, a transparent resin plate such as that of an acryl-based resin or a polycarbonate-based resin, or a glass plate is used. As the touch panel, a touch panel of any type such as resistive film type, capacitance type, optical type or ultrasonic type is used.

As the optical film with a pressure sensitive adhesive on both sides 50, one cut to a product size consistent with an image display size in advance is suitably used in formation of the image display device. The method for bonding the image display cell 60 to the optical film with a pressure sensitive adhesive on both sides 55, and the method for bonding the front transparent member 70 to the optical film with a pressure sensitive adhesive on both sides 55 are not particularly limited, and bonding can be performed by various kinds of known methods after the protective sheets 31 and 32 attached on the surfaces of the first pressure sensitive adhesive layer 21 and the second pressure sensitive adhesive layer 22, respectively, are peeled off.

Since the optical film with a pressure sensitive adhesive on both sides according to the present invention includes the first pressure sensitive adhesive layer and the second pressure sensitive adhesive layer, it is not necessary to provide an extra liquid adhesive or pressure sensitive adhesive sheet in a bonding step for forming an image display device. Therefore, contamination due to protrusion of a liquid resin or a pressure sensitive adhesive sheet is prevented, and also the production process is simplified.

The order of bonding is not particularly limited, bonding of the image display cell 60 to the first pressure sensitive adhesive layer 21 of the optical film with a pressure sensitive adhesive on both sides 55 may precede, or bonding of the front transparent member 70 to the second pressure sensitive adhesive layer 22 of the optical film with a pressure sensitive adhesive on both sides 55 may precede. The former bonding and the latter bonding may be performed in parallel. For improving workability in bonding and axis precision of the optical film, it is preferred that a first bonding step of bonding the optical film 10 and the image display cell 60 to each other with the first pressure sensitive adhesive layer interposed therebetween after peeling off the protective sheet 31 from the surface of the first pressure sensitive adhesive layer 21 is performed, followed by a second bonding step of peeling off the protective sheet 32 from the surface of the second pressure sensitive adhesive layer 22, and bonding the optical film 10 and the front transparent member 70 to each other with the second pressure sensitive adhesive layer 22 interposed therebetween.

It is preferred to perform degassing for removing bubbles at the interface between the second pressure sensitive adhesive layer 22 and the front transparent member 70, and in the vicinity of a non-flat portion such as the printed portion 70a formed on the front transparent member 70 after the optical film and the front transparent member are bonded to each other. As a degassing method, an appropriate method such as heating, pressurization or pressure reduction can be employed. For example, it is preferred that bonding is performed while ingress of bubbles is suppressed under reduced pressure and heating, and pressurization is then performed in parallel with heating through autoclave or the like for the purpose of, for example, suppressing delay bubbles. Particularly, when the storage elastic modulus G_{80° C.} of the second pressure sensitive adhesive layer 22 at 80° C. falls within a predetermined range, the second pressure sensitive adhesive layer follows the shape of a non-flat portion such as a level difference through the heating treatment, and therefore generation of gaps is suppressed even when the front transparent member has a non-flat portion.

When degassing is performed by heating, the heating temperature is in a range of generally about 30° C. to 150° C., preferably 40° C. to 130° C., more preferably 50° C. to 120° C., further preferably 60° C. to 100° C. When pressurization is performed, the pressure is in a range of generally about 0.05 MPa to 2 MPa, preferably 0.1 MPa to 1.5 MPa, more preferably 0.2 MPa to 1 MPa.

When the pressure sensitive adhesive that forms the second pressure sensitive adhesive layer is a curable pressure sensitive adhesive containing a curable monomer or oligomer, it is preferred that the second pressure sensitive adhesive layer is cured after the optical film 10 and the front transparent member 70 are bonded to each other. By curing the second pressure sensitive adhesive layer, reliability of adhesion between the optical film 10 and the front transparent member 70 in the image display device can be improved. When the heating or pressurization is performed for the purpose of removing bubbles and the like after the optical film and the front transparent member are bonded to each other, it is preferred that curing of the second pressure sensitive adhesive layer is performed after removal of bubbles. By performing curing of the second pressure sensitive adhesive layer after removal of bubbles, generation of delay bubbles is suppressed.

The method for curing the second pressure sensitive adhesive layer is not particularly limited. When photocuring is performed, a method is preferred in which an activated ray such as an ultraviolet ray is applied through the front transparent member 70. When the front transparent member 70 has a non-transparent portion such as the printed portion 70a, an active ray is not applied to immediately below the printed portion, but transfer of radicals generated in a portion irradiated with light causes the pressure sensitive adhesive proceeds to be cured to some degree in a portion which is not irradiated with light.

By using the optical film with a pressure sensitive adhesive on both sides according to the present invention, a bonding step can be simplified in production of an image display device employing an interlayer filling structure as described above. Further, by adjusting the thickness and elastic modulus of the pressure sensitive adhesive layer, glue missing and glue contamination are suppressed, and ingress of bubbles between the optical film and the front transparent plate or the touch panel can be suppressed, so that a high-quality image display device can be provided.

### EXAMPLES

The present invention will be described more specifically below by showing examples and comparative examples, but the present invention is not limited to these Examples.

### Example 1

### Polarizing Plate

A polarizing plate (polarization degree: 99.995%) with a transparent protective film laminated on each of both surfaces of a polarizer formed of a 25 μm-thick stretched polyvinyl alcohol film impregnated with iodine was used. The transparent protective film on one surface (image display cell side) of the polarizer was a retardation film formed of a 40 μm-thick triacetyl cellulose film, and the transparent protective film on the other surface (viewing side) was a 60 μm-thick triacetyl cellulose film.

<Formation of Cell-Side Pressure Sensitive Adhesive Layer (First Pressure Sensitive Adhesive Layer)>

(Preparation of Base Polymer)

97 parts of butyl acrylate, 3 parts of acrylic acid, 0.2 parts of azobisisobutyronitrile as a polymerization initiator and 233 parts of ethyl acetate were introduced into a separable flask provided with a thermometer, a stirrer, a reflux cooling tube and a nitrogen gas inlet, and a nitrogen gas was then fed to perform nitrogen purge for 1 hour while the mixture was stirred. Thereafter, the flask was heated to 60° C., the mixture was reacted for 7 hours to obtain an acryl-based polymer having a weight average molecular weight (Mw) of 1100000.

(Preparation of Pressure Sensitive Adhesive Composition)

A pressure sensitive adhesive composition (solution) was prepared by adding 0.8 part by weight of trimethylolpropane tolylene diisocyanate (“CORONATE L” manufactured by Nippon Polyurethane Industry Co., Ltd.) as an isocyanate-based crosslinker and 0.1 part of a silane coupling agent (“KBM-403” manufactured by Shin-Etsu Chemical Co., Ltd.) to the acryl-based polymer solution (solid content was taken as 100 parts by weight).

(Formation and Crosslinking of Pressure Sensitive Adhesive Layer)

The pressure sensitive adhesive composition solution was applied onto a separator (38 μm-thick polyethylene terephthalate-based film having a surface subjected to a release treatment) so as to have a thickness of 20 μm after drying, and dried at 100° C. for 3 minutes to remove the solvent, thereby obtaining a pressure sensitive adhesive layer. Thereafter, the pressure sensitive adhesive layer was heated at 50° C. for 48 hours to perform a crosslinking treatment (hereinafter, this pressure sensitive adhesive layer is referred to as a “pressure sensitive adhesive layer A”)

<Formation of Viewing-Side Pressure Sensitive Adhesive Layer (Second Pressure Sensitive Adhesive Layer)>

(Preparation of Base Polymer)

As a base polymer, a block copolymer of butyl acrylate (BA) and methyl methacrylate (MMA) (BA/MMA=2/1; weight average molecular weight: 100000) was used (hereinafter, this base polymer is referred to as a “polymer 1”).

(Preparation of Pressure Sensitive Adhesive Composition)

80 parts by weight of the polymer 1 and 20 parts by weight of a plasticizer were dissolved in 120 parts by weight of toluene to prepare a pressure sensitive adhesive composition (solution). As the plasticizer, an acryl oligomer having a weight molecular weight of about 3000 (“ARUFON UP-1000” manufactured by Toagosei Company, Limited) was used.

(Formation of Pressure Sensitive Adhesive Layer)

The pressure sensitive adhesive composition solution was applied onto a separator so as to have a thickness of 150 μm after drying, and dried at 100° C. for 3 minutes to remove the solvent, thereby obtaining a pressure sensitive adhesive layer (hereinafter, this pressure sensitive adhesive layer is referred to as a “pressure sensitive adhesive layer B1”).

<Preparation of Optical Film with Pressure Sensitive Adhesive on Both Sides>

The pressure sensitive adhesive layer A was bonded to one surface of the polarizing plate as a cell-side pressure sensitive adhesive layer. Thereafter, the pressure sensitive adhesive layer B1 was bonded to the other surface of the polarizing plate as a viewing side pressure sensitive adhesive layer, the separator was then peeled off, and the pressure sensitive adhesive layer B1 was bonded onto the above-mentioned pressure sensitive adhesive layer B1 to form a pressure sensitive adhesive layer having two pressure sensitive adhesive layers B1 (total thickness: 300 μm).

In this way, an optical film with a pressure sensitive adhesive on both sides with a 20 μm-thick pressure sensitive adhesive layer bonded to one surface of a polarizing plate (optical film), a 300 μm-thick pressure sensitive adhesive layer bonded to the other surface, and a separator releasably attached on each of the pressure sensitive adhesive layers was obtained.

<Cutting>

The optical film with a pressure sensitive adhesive on both sides was punched to a size of 48 mm×98 mm with a Thompson blade. 50 optical films with a pressure sensitive adhesive on both sides, which were punched to the same size, were stacked on one another, the films were held from the top and the bottom thereof using a vise-like tool, and a pressure was applied so that the pressure sensitive adhesive layer protruded from the end surface of the optical film. In this state, using a rotary blade, the optical film was trimmed 0.5 mm inside the end surface together with the pressure sensitive adhesive layer as well as the optical film and the separator. Thereafter, the pressure was released to obtain a polarizing plate with a pressure sensitive adhesive on both sides, which was cut to a product size.

<Preparation of Pseudo Image Display Device for Evaluation>

A flat glass plate (0.7 mm×50 mm×100 mm) was bonded to one surface (pressure sensitive adhesive layer A side) of a polarizing plate with a pressure sensitive adhesive on both sides, and a glass plate (0.7 mm×50 mm×100 mm; ink printing width: 10 mm from end) with a black ink (thickness: 10 μm) printed frame-wise on the peripheral edge was bonded to the other surface (pressure sensitive adhesive layer B side) to prepare a pseudo image display device for evaluation.

First, the separator on the pressure sensitive adhesive layer A side of the polarizing plate with a pressure sensitive adhesive on both sides was peeled off, and the polarizing plate was then placed on and bonded to one surface of a flat glass plate in a manner that the pressure sensitive adhesive layer was in contact with the glass surface. Thereafter, the release film on the pressure sensitive adhesive layer B side was peeled off, the polarizing plate was placed in a manner that the printed surface of a printed glass plate and the pressure sensitive adhesive layer were in contact with each other, and the polarizing plate and the glass plate were bonded to each other by performing thermocompression using a vacuum thermocompression device (temperature: 80° C.; pressure: 0.1 MPa; pressure retention time: 5 seconds). Thereafter, autoclave was performed (50° C., 0.5 MPa, 30 minutes).

### Examples 2 and 3

As the viewing side pressure sensitive adhesive layer B, a pressure sensitive adhesive composition (solution) having the composition shown in Table 1 was prepared. As a tackifier, a styrene oligomer (“YS Resin SX-85” manufactured by Yasuhara Chemical Co., LTD; softening point: 85° C.) was used in Example 2, and a nuclear hydrogenated terpene phenol (“YS Polyster NH” manufactured by Yasuhara Chemical Co., LTD; softening point: 130° C.) was used in Example 3. The pressure sensitive adhesive in each of Examples 2 and 3 is a photocurable pressure sensitive adhesive containing phenyl glycidyl ether acrylate (“New Frontier PGA” manufactured by Dai-ichi Kogyo Seiyaku Co., Ltd.) as a photocurable acryl-based monomer, and 1-hydroxycyclohexylphenylketone (“IRGACURE 184” manufactured by Ciba Specialty Chemicals Corporation) as a photoradical generator.

A polarizing plate with a pressure sensitive adhesive on both sides was prepared in the same manner as in Example 1 except that a photocurable pressure sensitive adhesive layer having the composition and thickness shown in Table 1 was used as the viewing side pressure sensitive adhesive layer B, and the polarizing plate was cut and bonded to glass plates in the same manner as in Example 1.

### Examples 4 to 6

### Preparation of Base Polymer

75 parts of 2-ethylhexyl acrylate (2EHA), 25 parts of hydroxyethyl acrylate HEA), 0.2 parts of azobisisobutyronitrile as a polymerization initiator and 233 parts of ethyl acetate were introduced into a separable flask provided with a thermometer, a stirrer, a reflux cooling tube and a nitrogen gas inlet, and a nitrogen gas was then fed to perform nitrogen purge for 1 hour while the mixture was stirred. Thereafter, the flask was heated to 70° C., the mixture was reacted for 5 hours to obtain an acryl-based polymer having a weight average molecular weight (Mw) of 700000 (hereinafter, this base polymer is referred to as a “polymer 2”).

<Preparation of Optical Film with Pressure Sensitive Adhesive on Both Sides and Preparation of Pseudo Image Display Device for Evaluation>

A pressure sensitive adhesive composition (solution) having the composition shown in Table 1 was prepared using the polymer 2. A polarizing plate with a pressure sensitive adhesive on both sides was prepared in the same manner as in Example 1 except that a pressure sensitive adhesive layer having the composition and thickness shown in Table 1 was used as the pressure sensitive adhesive layer B. In Example 4, a pressure sensitive adhesive solution was applied onto a separator, dried, and then heated at 50° C. for 48 hours to perform a crosslinking treatment.

Thereafter, the optical film with a pressure sensitive adhesive on both sides was cut and bonded to glass plates in the same manner as in Example 1.

### Examples 2a, 3a, 5a and 6a

Optical films with a pressure sensitive adhesive on both sides, which were similar to those in Examples 2, 3, 5 and 6, respectively, were prepared, and cut and bonded to glass plates. After the autoclave, an ultraviolet ray was applied through the viewing side glass plate using a high-pressure mercury lamp (10 mW/cm²), so that the photocurable pressure sensitive adhesive was cured (integrated light amount: 3000 mJ/cm²).

### Examples 7 to 14

The tackifier added to the pressure sensitive adhesive B1 and the thickness of the pressure sensitive adhesive layer in Example 1 were changed as shown in Table 1. Otherwise in the same manner as in Example 1, a polarizing plate with a pressure sensitive adhesive on both sides was prepared, and cut and bonded to glass plates. As a tackifier, a styrene oligomer (“YS Resin SX-100” manufactured by Yasuhara Chemical Co., LTD; softening point: 100° C.) was used in Example 11, and a hydrogenated rosin ester (“PINECRYSTAL KE-311” manufactured by Arakawa Chemical Industries, Ltd.; softening point: 95° C.) was used in Example 12.

### Comparative Example 1

The thickness of the viewing side pressure sensitive adhesive layer B1 in Example 1 was changed to 20 μm (only one layer). Otherwise in the same manner as in Example 1, a film with a pressure sensitive adhesive on both sides, and a pseudo image display device for evaluation were prepared.

### Comparative Example 2

In Comparative Example 1, only punching with a Thompson blade was performed, and trimming with a rotary blade was not performed in cutting. Otherwise in the same manner as in Comparative Example 1, a film with a pressure sensitive adhesive on both sides, and a pseudo image display device for evaluation were prepared.

### Comparative Example 3

A film with a pressure sensitive adhesive on one side, which had the pressure sensitive adhesive layer A bonded to one surface of a polarizing plate and which did not have a pressure sensitive adhesive on the other surface, was prepared. The optical film with a pressure sensitive adhesive on one side was punched with a Thompson blade, a separator on the pressure sensitive adhesive layer was peeled off, and the optical film was then placed on and bonded to one surface of a flat glass plate in a manner that the pressure sensitive adhesive layer was in contact with the glass surface.

In the same manner as in Example 1, a 150 μm-thick pressure sensitive adhesive layer B1 was formed on the separator, the pressure sensitive adhesive layer-formed surfaces of the two pressure sensitive adhesive layers with a separator were bonded to each other to form a pressure sensitive adhesive layer with a separator temporarily attached on each of both surfaces of a 300 μm-thick pressure sensitive adhesive layer.

The separator on one surface of the pressure sensitive adhesive layer was peeled off, the pressure sensitive adhesive layer was bonded onto the polarizing plate bonded on the glass plate, and the separator on the other surface of the pressure sensitive adhesive layer was peeled off. Thereafter, in the same manner as in Example 1, the printed surface of a printed glass plate and the pressure sensitive adhesive layer were bonded to each other through vacuum thermocompression and autoclave.

### Comparative Example 4

### Preparation of Liquid Adhesive

As shown in Table 1, 70 parts by weight of a tackifier (40 parts by weight of a nuclear hydrogenated terpene phenol and 30 parts by weight of an acryl oligomer) and 30 parts by weight of an acryl-based monomer (phenyl glycidyl ether acrylate) were heated/stirred/dissolved at 100° C. for 2 hours in a flask, and then cooled to 50° C. 5 parts by weight of photopolymerization initiator (1-hydroxycyclohexylphenylketone) was added to the cooled solution, and the mixture was heated/stirred/dissolved at 50° C. for 2 hours, and then cooled. Thereafter, the solution was degassed in vacuum (700 Pa) for 1 hour to prepare an UV-curable liquid adhesive composition (solution) which did not contain a base polymer.

<Preparation of Pseudo Image Display Device for Evaluation>

Operations up to and including bonding of an optical film with a pressure sensitive adhesive on one side to a flat glass plate were performed in the same manner as in Comparative Example 3. Thereafter, an appropriate amount of the UV-curable liquid adhesive composition (solution) was applied onto a polarizing plate bonded on a glass plate, and the polarizing plate was placed in a manner that the printed surface of a printed glass plate and the liquid adhesive were in contact with each other. Thereafter the polarizing plate and the printed glass plate were bonded to each other using a vacuum bonding device (temperature: 25° C., pressure: 0.003 MPa, pressure retention time: 5 seconds), an ultraviolet ray was applied through the viewing side glass plate using a high-pressure mercury lamp (10 mW/cm²), so that the adhesive was cured (integrated light amount: 6000 mJ/cm²).

[Evaluation]

<Evaluation of End Surface (Side Surface) of Optical Film with Pressure Sensitive Adhesive>

The side surface of the pseudo image display devices was observed. Protrusion of the adhesive (pressure sensitive adhesive) provided for interlayer filling from the end surface of the laminate was observed in Comparative Example 3 and Comparative Example 4.

(Tackiness of End Surface)

The side surface of the optical film with a pressure sensitive adhesive was touched with a hand to check tackiness. There was no tackiness in each of Examples and Comparative Example 1, whereas there was tackiness in Comparative Example 2 (not evaluated in Comparative Examples 3 and 4).

The vicinity of the end surface of each optical film with a pressure sensitive adhesive was observed with a digital microscope, and a distance (longest part) W2 between the side surface of the polarizing plate and the pressure sensitive adhesive layer B (viewing side pressure sensitive adhesive layer) was measured. In each of Examples and Comparative Example 1 where the end surface was trimmed in a pressurized state, there was no tackiness probably because the pressure sensitive adhesive layer was located inner side than the end surface of the optical film as shown in Table 1. It is apparent that the distance W2 has a certain correlation with the thickness and storage elastic modulus of the pressure sensitive adhesive layer.

(Evaluation of Glue Missing on End Surface)

50 optical films with a pressure sensitive adhesive were stacked on one another, packaged, held on a bed of a truck, transported in this state for 10 hours, and then opened. No glue missing occurred in each of Examples and Comparative Example 1, whereas glue missing of 350 μm or greater occurred in 8 optical films among 50 optical films in Comparative Example 2. (not evaluated in Comparative Examples 3 and 4).

<Storage Elastic Modulus of Pressure Sensitive Adhesive Layer>

The separator was peeled off from the pressure sensitive adhesive layer (before being bonded to the optical film) in each of the Examples and Comparative Examples, and a plurality of pressure sensitive adhesive layers were laminated to a thickness of about 1.5 mm. The laminate thus obtained was used as a measurement sample. A dynamic viscoelasticity was measured under the following conditions using “Advanced Rheometric Expansion System (ARES)” manufactured by Rheometric Scientific, Inc., and a storage elastic modulus G′₂₅° C. of the sample at 25° C. and a storage elastic modulus G′₈₀° C. of the sample at 80° C. were read from the measurement results. Using a similar method, a storage elastic modulus was measured for the cured pressure sensitive adhesive layer in each of Examples 2a, 3a, 5a and 6a.

### (Measurement Conditions)

Deformation mode: torsion

Measurement Frequency: 1 Hz

Temperature elevation rate: 5° C./minute

Measurement temperature: −50 to 150° C.

Shape: parallel plate (8.0 mmφ)

<Bubbles>

The vicinity of the inside of a black ink-printed portion in the pseudo image display device for evaluation was observed with a digital microscope at a magnification of 20 to check presence/absence of bubbles in the pressure sensitive adhesive layer. In addition, after the pseudo image display device for evaluation was placed in an oven at 85° C. for 48 hours, presence/absence of bubbles was checked using a same method.

[Evaluation Results]

Table 1 shows a list of compositions of the viewing side pressure sensitive adhesive layer and evaluation results for each of the Examples and Comparative Examples. In Table 1, the softening point of each tackifier is also shown.

TABLE 1

| | | | | Example | Example | Example | Example | Example | Example | Example | Example |
|---|---|---|---|---|---|---|---|---|---|---|---|
| | | | | 1 | 2 | 2a | 3 | 3a | 4 | 5 | 5a |
| Pressure | base | polymer 1 | | 80 | 30 | 30 | 40 | 40 | — | — | — |
| sensitive | polymer | (Ba/MMA) | | | | | | | | | |
| adhesive | | polymer 2 | | — | — | — | — | — | 100 | 40 | 40 |
| composition | | (2EHA/HEA) | | | | | | | | | |
| (wt. | plasticizer | acryl oligomer | | 20 | — | — | — | — | — | — | — |
| part) | tackifier | hydrogenated | 130° C. | — | — | — | 50 | 50 | — | 50 | 50 |
| | | terpene phenol | | | | | | | | | |
| | | styrene | 85° C. | — | 60 | 60 | — | — | — | — | — |
| | | oligomer | | | | | | | | | |
| | | styrene | 100° C. | — | — | — | — | — | — | — | — |
| | | oligomer | | | | | | | | | |
| | | hydrogenated | 95° C. | — | — | — | — | — | — | — | — |
| | | rosin ester | | | | | | | | | |
| | cross- | isocyanate-based | | — | — | — | — | — | 0.5 | — | — |
| | linker | crosslinker | | | | | | | | | |
| | photo- | acryl-based monomer | | — | 10 | 10 | 10 | 10 | — | 10 | 10 |
| | curable | (PGA) | | | | | | | | | |
| | compound | radical generator | | — | 5 | 5 | 5 | 5 | — | 5 | 5 |
| | solvent | ethyl acetate | | — | — | — | — | — | 233 | 93 | 93 |
| | | toluene | | 120 | 45 | 45 | 60 | 60 | — | — | — |
| pressure sensitive adhesive layer | | | | 300 | 30 | 30 | 150 | 150 | 300 | 150 | 150 |
| thickness (μm) | | | | (150 × 2) | | | | | (150 × 2) | | |
| storage elastic | | G′_{25° C.} | | 3.0 × 10⁵ | 1.2 × 10⁵ | 1.2 × 10⁵ | 9.0 × 10⁶ | 9.0 × 10⁶ | 1.2 × 10⁵ | 3.1 × 10⁵ | 3.1 × 10⁵ |
| modulus | | G′_{80° C.} | | 9.0 × 10⁴ | 1.1 × 10² | 1.1 × 10² | 1.6 × 10⁴ | 1.6 × 10⁴ | 5.4 × 10⁴ | 7.2 × 10³ | 7.2 × 10³ |
| | | G′_{80° C.} | | | | 1.3 × 10³ | | 9.0 × 10⁴ | | | 5.0 × 10⁴ |
| | | (after photocuring) | | | | | | | | | |
| bubble | | Bubble | | absent | absent | absent | absent | absent | absent | absent | absent |
| evaluation of | | (before heating) | | | | | | | | | |
| image display | | Bubble | | absent | present | absent | absent | absent | absent | absent | absent |
| device | | (after heating) | | | | | | | | | |
| distance between optical film edge to pressure | | | | 300 | 300 | 300 | 150 | 150 | 300 | 150 | 150 |
| sensitive adhesive | | | | | | | | | | | |
| | | | | Example | Example | Example | Example | Example | Example | Example | Example |
| | | | | 6 | 6a | 7 | 8 | 9 | 10 | 11 | 12 |
| Pressure | base | polymer 1 | | — | — | 40 | 40 | 40 | 40 | 40 | 40 |
| sensitive | polymer | (Ba/MMA) | | | | | | | | | |
| adhesive | | polymer 2 | | 60 | 60 | — | — | — | — | — | — |
| composition | | (2EHA/HEA) | | | | | | | | | |
| (wt. | plasticizer | acryl oligomer | | 30 | 30 | 10 | 10 | 10 | 10 | 10 | 10 |
| part) | tackifier | hydrogenated | 130° C. | — | — | — | — | — | 50 | — | — |
| | | terpene phenol | | | | | | | | | |
| | | styrene | 85° C. | — | — | 50 | 50 | 50 | — | — | — |
| | | oligomer | | | | | | | | | |
| | | styrene | 100° C. | — | — | — | — | — | — | 50 | — |
| | | oligomer | | | | | | | | | |
| | | hydrogenated | 95° C. | — | — | — | — | — | — | — | 50 |
| | | rosin ester | | | | | | | | | |

| | | | | | | | | | |
|---|---|---|---|---|---|---|---|---|---|
| cross- | isocyanate-based | — | — | — | — | — | — | — | — |
| linker | crosslinker | | | | | | | | |
| photo- | acryl-based monomer | 10 | 10 | — | — | — | — | — | — |
| curable | (PGA) | | | | | | | | |
| compound | radical generator | 5 | 5 | — | — | — | — | — | — |
| solvent | ethyl acetate | 140 | 140 | — | — | — | — | — | — |
| | toluene | — | — | 60 | 60 | 60 | 60 | 60 | 60 |

| pressure sensitive adhesive layer | | 30 | 30 | 30 | 150 | 300 | 150 | 150 | 150 |
|---|---|---|---|---|---|---|---|---|---|
| thickness (μm) | | | | | | | | | |
| storage elastic | G′_{25° C.} | 1.1 × 10⁴ | 1.1 × 10⁴ | 3.0 × 10⁵ | 3.0 × 10⁵ | 3.0 × 10⁵ | 9.2 × 10⁶ | 1.2 × 10⁶ | 2.6 × 10⁵ |
| modulus | G′_{80° C.} | 1.1 × 10³ | 1.1 × 10³ | 5.0 × 10³ | 5.0 × 10³ | 5.0 × 10³ | 2.0 × 10⁴ | 2.0 × 10⁴ | 7.2 × 10³ |
| | G′_{80° C.} | | 7.8 × 10³ | | | | | | |
| | (after photocuring) | | | | | | | | |
| bubble | Bubble | absent | absent | absent | absent | absent | absent | absent | absent |
| evaluation of | (before heating) | | | | | | | | |
| image display | Bubble | absent | absent | absent | absent | absent | absent | absent | absent |
| device | (after heating) | | | | | | | | |

| | | | | | | | | |
|---|---|---|---|---|---|---|---|---|
| distance between optical film edge to pressure | 3 | 3 | 20 | 120 | 250 | 50 | 100 | 150 |
| sensitive adhesive | | | | | | | | |

| | | | | Example | Example | Comparative | Comparative | Comparative | Comparative |
|---|---|---|---|---|---|---|---|---|---|
| | | | | 13 | 14 | Example 1 | Example 2 | Example 3 | Example 4 |
| Pressure | base | polymer 1 | | 30 | 60 | 80 | 80 | 80 | — |
| sensitive | polymer | (Ba/MMA) | | | | | | | |
| adhesive | | polymer 2 | | | | — | — | — | — |
| composition | | (2EHA/HEA) | | | | | | | |
| (wt. | plasticizer | acryl oligomer | | 10 | — | 20 | 20 | 20 | 30 |
| part) | tackifier | hydrogenated | 130° C. | — | — | — | — | — | 40 |
| | | terpene phenol | | | | | | | |
| | | styrene | 85° C. | 60 | 40 | — | — | — | — |
| | | oligomer | | | | | | | |
| | | styrene | 100° C. | — | — | — | — | — | — |
| | | oligomer | | | | | | | |
| | | hydrogenated | 95° C. | — | — | — | — | — | — |
| | | rosin ester | | | | | | | |

| | | | | | | | |
|---|---|---|---|---|---|---|---|
| cross- | isocyanate-based | — | — | — | — | — | — |
| linker | crosslinker | | | | | | |
| photo- | acryl-based monomer | — | — | — | — | — | 30 |
| curable | (PGA) | | | | | | |
| compound | radical generator | — | — | — | — | — | 5 |
| solvent | ethyl acetate | — | — | — | — | — | — |
| | toluene | 45 | 90 | 120 | 120 | 120 | — |

| pressure sensitive adhesive layer | | 150 | 150 | 20 | 20 | 300 | |
|---|---|---|---|---|---|---|---|
| thickness (μm) | | | | | | (150 × 2) | |
| storage elastic | G′_{25° C.} | 2.2 × 10⁵ | 6.9 × 10⁵ | 3.0 × 10⁵ | 3.0 × 10⁵ | 3.0 × 10⁵ | |
| modulus | G′_{80° C.} | 4.0 × 10³ | 1.9 × 10⁴ | 9.0 × 10⁴ | 9.0 × 10⁴ | 9.0 × 10⁴ | |
| | G′_{80° C.} | | | | | | 4.9 × 10⁴ |
| | (after photocuring) | | | | | | |
| bubble | Bubble | absent | absent | absent | present | present | absent |
| evaluation of | (before heating) | | | | | | |
| image display | Bubble | absent | absent | absent | present | present | absent |
| device | (after heating) | | | | | | |

| | | | | |
|---|---|---|---|---|
| distance between optical film edge to pressure | 150 | 150 | 300 | 0 |
| sensitive adhesive | | | | |

In Comparative Examples 1 and 2, the thickness of the pressure sensitive adhesive layer B (second pressure sensitive adhesive layer) was small, and therefore there were bubbles with the ink-printed portion of the front transparent plate as an origination point. In Comparative Examples 3 and 4, the bonding step was complicated, and protrusion of the adhesive from the end surface occurred.

On the other hand, in each of the Examples using the optical film with a pressure sensitive adhesive on both sides, the front transparent member could be bonded in a simple step, and even when a glass plate having an ink-printed portion was used as the front transparent member, ingress of bubbles did not occur, and thus proper bonding could be performed.

Comparison between Example 1 and Examples 7 to 14 shows that by adding a tackifier in the pressure sensitive adhesive, the storage elastic modulus at room temperature can be appropriately adjusted, and various temperature dependencies can be imparted to the storage elastic modulus.

Comparison between Example 2 and Example 2a shows that by photocuring the curable pressure sensitive adhesive after bonding, generation of bubbles (delay bubbles) is suppressed even when the display device is exposed to a heating environment. Thus, it is apparent that by using a curable pressure sensitive adhesive as an interlayer filler, adhesiveness and bonding workability are improved because the storage elastic modulus is relatively small at the time of bonding, and the elastic modulus is increased by subsequent curing, so that long-term reliability of adhesion can be achieved.

### DESCRIPTION OF REFERENCE CHARACTERS

10 optical film
11 polarizing plate
13, 14 optical film
21, 22 pressure sensitive adhesive layer
31, 32 protective sheet
50 optical film with pressure sensitive adhesive on both sides
60 image display cell
70 front transparent member (touch panel or front transparent plate)
100 image display device

1. An optical film with a pressure sensitive adhesive on both sides, which is to be disposed between a front transparent plate or a touch panel and an image display cell, wherein
the optical film with a pressure sensitive adhesive on both sides comprises: an optical film including a polarizing plate; a first pressure sensitive adhesive layer provided on a surface of the optical film at a side configured to be bonded to the image display cell; and a second pressure sensitive adhesive layer provided on a surface of the optical film at a side configured to be bonded to the transparent plate or the touch panel,
further a protective sheet is releasably attached on each of the first pressure sensitive adhesive layer and the second pressure sensitive adhesive layer, and
a thickness of the second pressure sensitive adhesive layer is 30 μm or more.

2. The optical film with a pressure sensitive adhesive on both sides according to claim 1, wherein a thickness of the first pressure sensitive adhesive layer is 3 to 30 μm.

3. The optical film with a pressure sensitive adhesive on both sides according to claim 1, wherein the second pressure sensitive adhesive layer has a storage elastic modulus of 1.0×10⁴ Pa to 1.0×10⁷ Pa at 25° C., and a storage elastic modulus of 1.0×10² Pa to 1×10⁵ Pa at 80° C.

4. The optical film with a pressure sensitive adhesive on both sides according to claim 1, wherein the second pressure sensitive adhesive layer contains a tackifier having a softening point of 50° C. to 150° C.

5. The optical film with a pressure sensitive adhesive on both sides according to claim 1, wherein a pressure sensitive adhesive that forms the second pressure sensitive adhesive layer comprises a base polymer containing a branched (meth)acrylic acid alkyl ester as a monomer unit.

6. The optical film with a pressure sensitive adhesive on both sides according to claim 1, wherein a pressure sensitive adhesive that forms the second pressure sensitive adhesive layer is a photocurable pressure sensitive adhesive containing a photocurable monomer or a photocurable oligomer.

7. The optical film with a pressure sensitive adhesive on both sides according to claim 6, wherein the second pressure sensitive adhesive layer has a storage elastic modulus of 1.0×10³ Pa to 1.0×10⁶ Pa at 80° C. after being cured by application of an active ray.

8. A method for producing an image display device,
in the image display device, an optical film including a polarizing plate is disposed on an image display cell with a first pressure sensitive adhesive layer interposed therebetween, and a front transparent plate or a touch panel is disposed on the polarizing plate with a second pressure sensitive adhesive layer interposed therebetween, wherein
the method comprises: a first bonding step of peeling off a protective film attached on the first pressure sensitive adhesive layer of the optical film with a pressure sensitive adhesive on both sides according to claim 1, and then bonding the optical film and the image display cell to each other with the first pressure sensitive adhesive layer interposed therebetween; and
a second bonding step of peeling off a protective sheet attached on the second pressure sensitive adhesive layer, and then bonding the optical film and the front transparent plate or the touch panel to each other with the second pressure sensitive adhesive layer interposed therebetween.

9. A method for producing an image display device,
in the image display device, an optical film including a polarizing plate is disposed on an image display cell with a first pressure sensitive adhesive layer interposed therebetween, and a front transparent plate or a touch panel is disposed on the polarizing plate with a second pressure sensitive adhesive layer interposed therebetween, wherein
the method comprises: a first bonding step of peeling off a protective film attached on the first pressure sensitive adhesive layer of the optical film with a pressure sensitive adhesive on both sides according to claim 6, and then bonding the optical film and the image display cell to each other with the first pressure sensitive adhesive layer interposed therebetween; and
a second bonding step of peeling off a protective sheet attached on the second pressure sensitive adhesive layer, and then bonding the optical film and the front transparent plate or the touch panel to each other with the second pressure sensitive adhesive layer interposed therebetween, and
after the second bonding step, an active ray is applied from the front transparent plate or touch panel side to cure the second pressure sensitive adhesive layer.
